(19) United States
(12) Patent Application Publication
(10) Pub. No.: US 2021/0013878 A1
(43) Pub. Date: Jan. 14, 2021

(54) POWER CONVERTER FAULT DETECTION

(71) Applicant: Ford Global Technologies, LLC, Dearborn, MI (US)

(72) Inventors: Yantao Song, Northville, MI (US); Baoming Ge, Okemos, MI (US); Lihua Chen, Farmington Hills, MI (US); Serdar Hakki Yonak, Ann Arbor, MI (US)

(21) Appl. No.: 16/507,883

(22) Filed: Jul. 10, 2019

(51) Int. Cl. H03K 17/082; H02M 7/5387; H02P 27/08; H02P 9/30; H02M 1/08; B60L 50/51

(52) U.S. Cl. CPC H03K 17/0828; H02M 7/53871; H02P 27/08; B60L 2210/40; H02M 1/08; B60L 50/51; H02P 9/305

(57) ABSTRACT

A vehicle powertrain has a traction battery, an electric machine, a power converter including a pair of series connected switches defining a phase leg for the electric machine, and a controller. The controller drives the switches with respective pulse width modulated signals to transfer power from the traction battery to the electric machine. Each of the respective pulse width modulated signals defines a low state and a high state. The controller further, responsive to a current flowing through one of the switches exceeding a predetermined threshold and the pulse width modulated signal for the other of the switches having the high state, stops driving the switches.

### TECHNICAL FIELD

This disclosure relates to the control of power electronic converters.

### BACKGROUND

A vehicle may be driven by operation of an electric machine. Energy from a traction battery may be provided to the electric machine via a variable voltage converter and inverter to increase a voltage associated with the energy and to transform current associated with the energy from direct current (DC) to alternating current (AC). The inverter may include a plurality of switching elements to facilitate the DC to AC transformation.

### SUMMARY

A vehicle powertrain includes a traction battery, an electric machine, a power converter having a pair of series connected switches defining a phase leg for the electric machine, and a controller. The controller drives the switches with respective pulse width modulated signals to transfer power from the traction battery to the electric machine. Each of the respective pulse width modulated signals defines a low state and a high state. The controller further, responsive to a current flowing through one of the switches exceeding a predetermined threshold and the pulse width modulated signal for the other of the switches having the high state, stops driving the switches.

A vehicle power system has a power converter including a pair of series connected switches defining a phase leg, and a controller programmed. The controller generates respective pulse width modulated signals to selectively turn the switches on and off. Each of the respective pulse width modulated signals defines a low state and a high state. Each of the switches is configured to pass current at a maximum operating value responsive to the corresponding pulse width modulated signal having the high state. The controller further, responsive to a current flowing through one of the switches exceeding a predetermined threshold less than the maximum operating value and the pulse width modulated signal for the other of the switches having the high state, stops generating the respective pulse width modulated signals prior to the current flowing through the one of the switches achieving the maximum operating value.

A method for operating a vehicle power system includes driving a pair of series connected switches of a power converter that define a phase leg for an electric machine with respective pulse width modulated signals to transfer power from a traction battery to the electric machine. Each of the respective pulse width modulated signals defines a low state and a high state. The method further includes, responsive to a current flowing through one of the switches exceeding a predetermined threshold and the pulse width modulated signal for the other of the switches having the high state, stopping the driving.

### BRIEF DESCRIPTION OF THE DRAWINGS

FIG. 1 is a schematic diagram of an electrified powertrain for a vehicle.

FIG. 2 is a block diagram of prior art circuitry for a bridge-based DC-DC converter.

FIG. 3 is a flow chart of an algorithm for shoot through fault detection.

FIG. 4 is a timing diagram showing conditions yielding detection of a shoot through fault condition.

FIG. 5 is a block diagram of circuitry for shoot through fault detection.

### DETAILED DESCRIPTION

Various embodiments of the present disclosure are described herein. However, the disclosed embodiments are merely exemplary and other embodiments may take various and alternative forms that are not explicitly illustrated or described. The figures are not necessarily to scale; some features may be exaggerated or minimized to show details of particular components. Therefore, specific structural and functional details disclosed herein are not to be interpreted as limiting, but merely as a representative basis for teaching one of ordinary skill in the art to variously employ the present invention. As those of ordinary skill in the art will understand, various features illustrated and described with reference to any one of the figures may be combined with features illustrated in one or more other figures to produce embodiments that are not explicitly illustrated or described. The combinations of features illustrated provide representative embodiments for typical applications. However, various combinations and modifications of the features consistent with the teachings of this disclosure may be desired for particular applications or implementations.

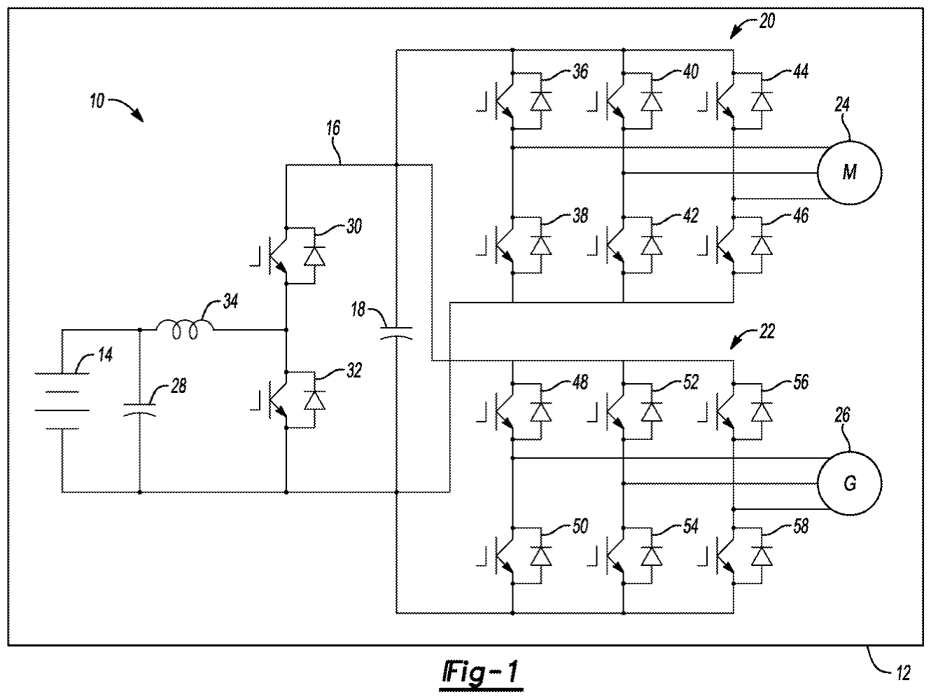

Bridge-based power electronics converters/inverters have been extensively used in EV/HEV's drive systems. As shown in FIG. 1, an electric drive system 10 for a vehicle 12 includes a traction battery 14, a bridge-based DC-DC converter 16, a DC-link capacitor 18, two DC-AC inverters, 20, 22, a motor 24, and a generator 26. The bridge-based DC-DC converter 16 includes a capacitor 28 in parallel with the traction battery 14, a pair of series connected switches 30, 32 (e.g., transistors), and an inductor 34 between the capacitor and series connected switches 30, 32. The DC-AC inverter 20 includes, in this example, three pairs of series connected switches 36, 38, 40, 42, 44, 46. Each of the pairs defines a corresponding phase leg for the motor 24. The DC-AC inverter 26 also includes three pairs of series connected switches 48, 50, 52, 54, 56, 58. Each of the pairs defines a corresponding phase leg for the motor generator 26.

A voltage associated with power from the traction battery 14 may be increased by operation of the bridge-based DC-DC converter 16 for eventual delivery to the DC-AC inverter 20 and thus the motor 24 to propel the vehicle 12. Likewise, regenerative power captured by the generator 26 may be passed through the DC-AC inverter 22 and so on for storage in the traction battery 14.

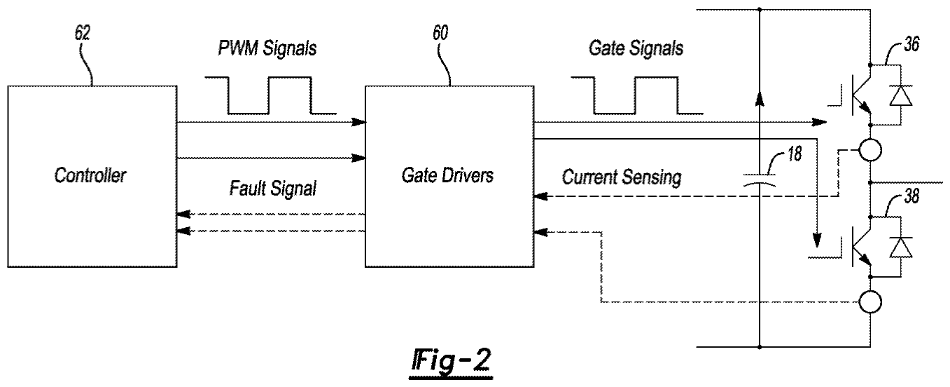

Shoot through faults can occur across the phase legs of the DC-AC inverters 20, 22. FIG. 2 shows one of the phase legs of the DC-AC inverter 20 along with a corresponding gate driver 60 and controller 62. Gate signals of the switches 36, 38 are normally complementary. In normal operating conditions, only one of the switches 36, 38 is turned on at any time. In the shoot through condition, the switches 36, 38 are on at the same time, and the high DC voltage source is directly short circuited by the low impedance formed by the on-state resistances of the switches 36, 38. The shoot through can generate a large current that is much higher than the normal operating current of the switches 36, 38.

To prevent shoot through faults, a dead time between gate signals of the switches 36, 38 is inserted. Even though the dead time is inserted, the switches 36, 38 may be mis-triggered to generate a shoot through fault due to noise, component variation characteristics, or software faults. This type of over-current detection is used to protect the switch components and the system from the effects of shoot through faults.

The switch current is measured and compared with a threshold. As the measured switch current exceeds the threshold, the over-current condition is flagged and the gate signals of the switches 36, 38, 40, 42, 44, 46 of the DC-AC inverter 20 are disabled. To distinguish the over-current condition from the normal operation conditions, the threshold must be higher than the maximum operating current of the switches 36, 38, 40, 42, 44, 46. This larger fault current may cause high voltage stress to the switches 36, 38, 40, 42, 44, 46 as the switches 36, 38, 40, 42, 44, 46 are turned off. As a result, a conservative and longer dead time is used to prevent shoot through faults. Longer dead times, however, can degrade operation and performance: The dead time sets a limit on the minimal pulse width of the pulse width modulated gate signal and therefore reduces the adjustable voltage range. For DC-AC inverters, the dead time significantly reduces DC voltage utilization, increases current harmonics, and reduces the torque control accuracy for the motor drive applications.

Here, a diagnostic strategy for shoot through faults of converters/inverters is proposed that considers measured switch currents and pulse width modulated signals of the switches. By way of example, the pulse width modulated signals of the switches 36, 38 are complementary, except for the duration of the dead time. As the pulse width modulated signal (gate signal) of the switch 38 is high (active), the switch 36 should be in the off state, and no current should flow through the switch 36. If a current flowing through the switch 36 is detected while the pulse width modulated signal of the switch 38 is high, then the switch 36 is mis-triggered or is not completely turned off and a shoot through fault may occur. Similarly, if a current flowing through the switch 38 is detected while the pulse width modulated signal of the switch 36 is high, then the switch 38 is mis-triggered or is not completely turned off and a shoot through fault may occur. The fault signal will be flagged and gate signals of all the switches 36, 38, 40, 42, 44, 46 will be disabled once the fault is detected.

More generally, responsive to the measured current through one switch of a phase leg exceeding a threshold, the status of the gate signal of the other switch of the phase leg is checked. If the gate signal of the other switch is high, then the one switch is in an abnormal status and a shoot through fault is detected. Likewise, responsive to the measured current through the other switch exceeding the threshold, the status of the gate signal of the one switch is checked. If the gate signal of the one switch is high, then the other switch is in an abnormal status and a shoot through fault is detected. Once the shoot through fault is detected, a fault signal is immediately generated and sent to a controller, and gate signals to all switches are disabled and the converter stops operating.

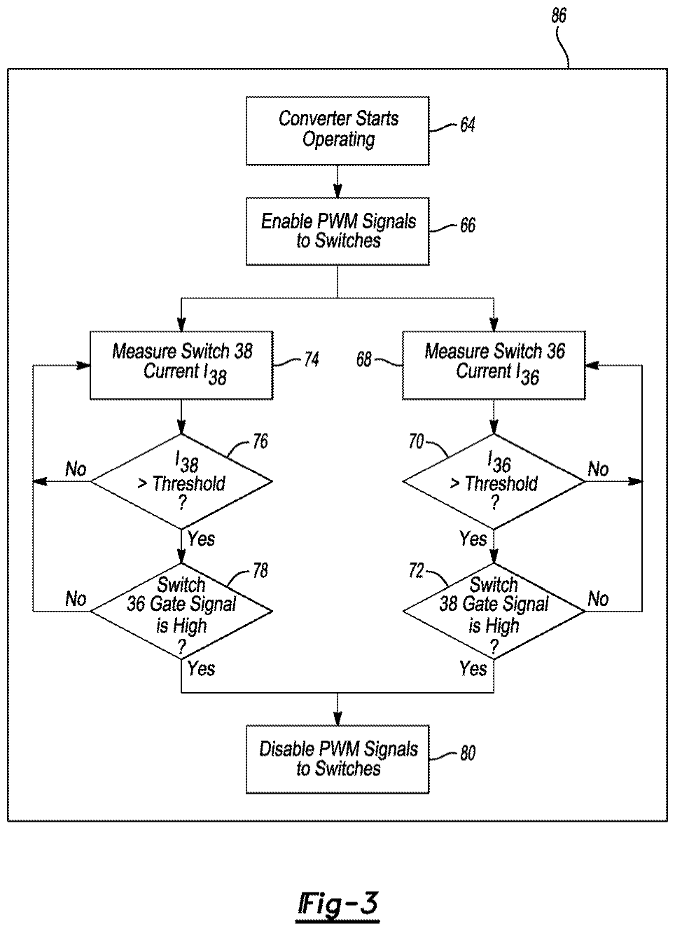

A flow chart of an algorithm is shown in FIG. 3. Although this example is described with reference to the DC-AC inverter 20, it is applicable to any appropriate converter or inverter. As the DC-AC inverter 20 begins to operate at operation 64, the pulse width modulated signals (gate signals) to the switches 36, 38 are enabled at operation 66.

At operation 68, current flowing through the switch 36 is measured. If the current is less than a predefined threshold at decision block 70, the algorithm returns to operation 68, and operation of the switches 36, 38 is maintained. If the current is greater than the predefined threshold, the algorithm proceeds to operation 72. If the pulse width modulated signal (gate signal) for the switch 38 is low (inactive), the algorithm returns to operation 68, and operation of the switches 38, 38 is maintained. If the pulse width modulated signal (gate signal) for the switch 38 is high, a fault is detected and pulse width modulated signals to the switches 36, 38, 40, 42, 44, 46 are disabled.

At operation 74, current flowing through the switch 38 is measured. If the current is less than a predefined threshold at decision block 76, the algorithm returns to operation 74. If the current is greater than the predefined threshold, the algorithm proceeds to operation 78. If the pulse width modulated signal for the switch 36 is low, the algorithm returns to operation 74. If the pulse width modulated signal for the switch 36 is high, a fault is detected and pulse width modulated signals to the switches 36, 38, 40, 42, 44, 46 are disabled.

As mentioned above, the conventional threshold for detecting over-current conditions must be higher than the maximum operating current of the switch. Here, however, the threshold can be much lower than the normal operating current (e.g., 10% of the maximum operating current, etc.), so the method can detect shoot through faults in early stages. This detection enables reduction of the dead time between gate signals of switches. Reducing dead time can increase DC voltage utilization, reduce the output current distortion and harmonics, and improve the torque control accuracy for the three-phase traction inverters.

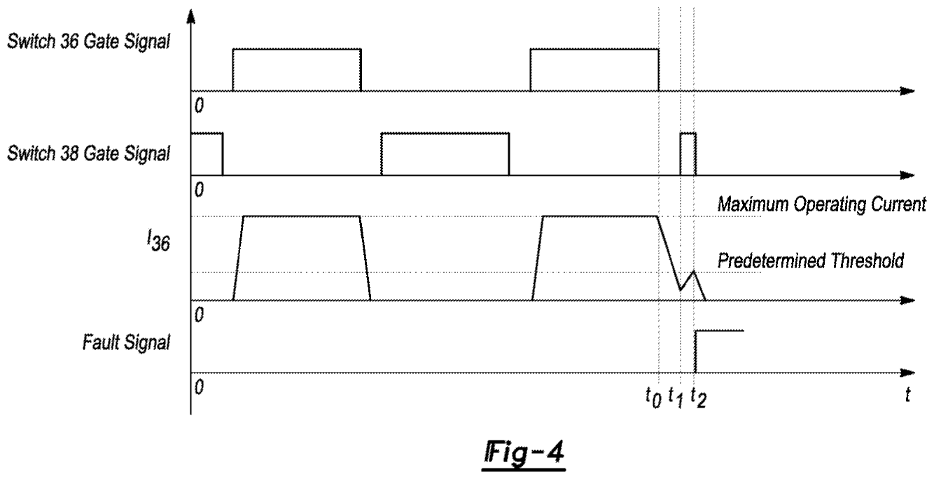

FIG. 4 shows the timing diagram of a shoot through fault detection based on the strategies contemplated herein. At time instant to, the gate signal of the switch 36 becomes low, and the current through the switch 36 starts to decrease. At time instant t₁, the switch 36 is still commutating; however, the gate signal of the switch 38 becomes high, and the switch 38 is forced to be turned on. Therefore, a shoot through fault is generated and the current flowing through the switch 36 quickly increases. As the current through the switch 36 achieves the predetermined threshold at time instant t₂, the shoot through fault is detected, a fault signal is generated, and the gate signals of the switches 36, 38 are immediately disabled. After the gate signals are disabled, the current through the switch 36 gradually decreases to zero. Then, the gate signals can be reenabled using known techniques.

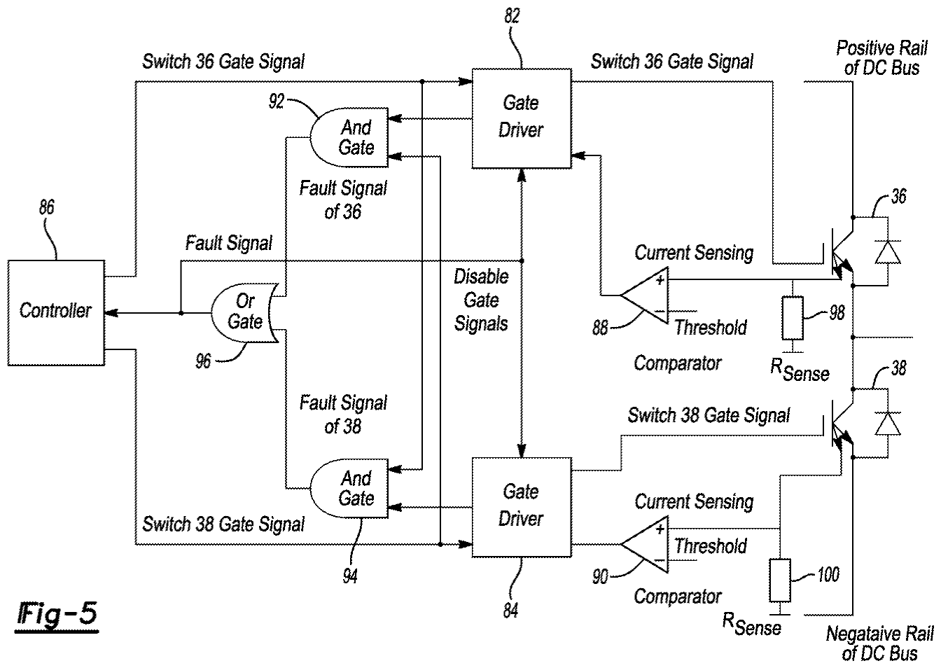

FIG. 5 shows an example detailed implementation of the proposed shoot through fault diagnostic system. Other implements, however, are of course possible. The switches 36, 38 can be insulated-gate bipolar transistors, metal-oxide-semiconductor field-effect transistors, or other types of controllable semiconductor devices. The system also includes gate drivers 82, 84, a controller 86, comparators 88, 90, logic gates 92, 94, 96, and sense resistors 98, 100. The gate drivers 82, 84 are respectively configured to provide the gate signals to the switches 36, 38. The semiconductor devices' embedded current sensors 98, 100 are used to monitor the currents flowing through the switches 36, 38 respectively. The comparators 88, 90 detect whether the sensed currents exceed the predetermined threshold. If so, such data is fed to the logic gates 92, 94, 96, which determine whether the current through one of the switches 36, 38 is greater than the predetermined threshold at the same time the gate signal for the other of the switches 36, 38 is high. If so, a fault is detected as described above. The gate drivers 82, 84 of the switches 36, 38 will be immediately disabled by the controller 86 to prevent fault propagation, and the fault signal is also sent such that the other switches 40, 42, 44, 46 are disabled.

The strategies herein use both switch current and gate signals to ensure a reliable shoot through diagnosis, and can be implemented by hardware, software, or a combination of the two. Shoot through faults can be detected before the current exceeds the maximum operating value of the switch. As a result, components may experience fewer issues. Moreover, the fault strategies herein permit the use of shorter dead times, which may increase DC voltage utilization, improve current quality for three-phase inverters, and improve toque control accuracy for traction inverters.

The algorithms, processes, methods, logic, or strategies disclosed may be deliverable to and/or implemented by a processing device, controller, or computer, which may include any existing programmable electronic control unit or dedicated electronic control unit. Similarly, the algorithms, processes, methods, logic, or strategies may be stored as data and instructions executable by a controller or computer in many forms including, but not limited to, information permanently stored on various types of articles of manufacture that may include persistent non-writable storage media such as ROM devices, as well as information alterably stored on writeable storage media such as floppy disks, magnetic tapes, CDs, RAM devices, and other magnetic and optical media. The algorithms, processes, methods, logic, or strategies may also be implemented in a software executable object. Alternatively, they may be embodied in whole or in part using suitable hardware components, such as Application Specific Integrated Circuits (ASICs), Field-Programmable Gate Arrays (FPGAs), state machines, controllers or other hardware components or devices, or a combination of hardware, software and firmware components.

The words used in the specification are words of description rather than limitation, and it is understood that various changes may be made without departing from the spirit and scope of the disclosure and claims. As previously described, the features of various embodiments may be combined to form further embodiments that may not be explicitly described or illustrated. While various embodiments may have been described as providing advantages or being preferred over other embodiments or prior art implementations with respect to one or more desired characteristics, those of ordinary skill in the art recognize that one or more features or characteristics may be compromised to achieve desired overall system attributes, which depend on the specific application and implementation. These attributes include, but are not limited to cost, strength, durability, life cycle cost, marketability, appearance, packaging, size, serviceability, weight, manufacturability, ease of assembly, etc. As such, embodiments described as less desirable than other embodiments or prior art implementations with respect to one or more characteristics are not outside the scope of the disclosure and may be desirable for particular applications.

What is claimed is:

1. A vehicle powertrain comprising:
a traction battery;
an electric machine;
a power converter including a pair of series connected switches defining a phase leg for the electric machine; and
a controller programmed to
drive the switches with respective pulse width modulated signals to transfer power from the traction battery to the electric machine, each of the respective pulse width modulated signals defining a low state and a high state, and
responsive to a current flowing through one of the switches exceeding a predetermined threshold and the pulse width modulated signal for the other of the switches having the high state, stop driving the switches.

2. The vehicle powertrain of claim 1, wherein the one of the switches is configured such that the current flowing through the one of the switches achieves a maximum operating value responsive to the pulse width modulated signal for the one of the switches having the high state and wherein the predetermined threshold is less than the maximum operating value.

3. The vehicle powertrain of claim 2, wherein the controller is further programmed to stop driving the switches prior to the current flowing through the one of the switches achieving the maximum operating value.

4. The vehicle powertrain of claim 1, wherein the controller is further programmed to, responsive to the current flowing through the one of the switches exceeding the predetermined threshold and the pulse width modulated signal for the other of the switches having the low state, maintain driving the switches.

5. The vehicle powertrain of claim 1, wherein the electric machine is a motor or generator.

6. The vehicle powertrain of claim 1, wherein the power converter is an inverter.

7. A vehicle power system comprising:
a power converter including a pair of series connected switches defining a phase leg; and
a controller programmed to
generate respective pulse width modulated signals to selectively turn the switches on and off, each of the respective pulse width modulated signals defining a low state and a high state and each of the switches being configured to pass current at a maximum operating value responsive to the corresponding pulse width modulated signal having the high state, and
responsive to a current flowing through one of the switches exceeding a predetermined threshold less than the maximum operating value and the pulse width modulated signal for the other of the switches having the high state, stop generating the respective pulse width modulated signals prior to the current flowing through the one of the switches achieving the maximum operating value.

8. The vehicle power system of claim 7, wherein the controller is further programmed to, responsive to the current flowing through the one of the switches exceeding the predetermined threshold and the pulse width modulated signal for the other of the switches having the low state, maintain generating the respective pulse width modulated signals.

9. The vehicle power system of claim 7 further comprising a traction battery and an electric machine, wherein the power converter is configured to provide power from the traction battery to the electric machine.

10. The vehicle power system of claim 9, wherein the electric machine is a motor or generator.

11. The vehicle power system of claim 7, wherein the power converter is an inverter.

12. A method for operating a vehicle power system comprising:
driving in a complementary fashion a pair of series connected switches, of a power converter, that define a phase leg for an electric machine with respective pulse width modulated signals to transfer power from a traction battery to the electric machine, each of the respective pulse width modulated signals defining a low state and a high state; and
responsive to current flowing through one of the switches exceeding a predetermined threshold and the pulse width modulated signal for the other of the switches having the high state, stopping the driving.

13. The method of claim 12, wherein the one of the switches is configured such that the current flowing through the one of the switches achieves a maximum operating value responsive to the pulse width modulated signal for the one of the switches having the high state and wherein the predetermined threshold is less than the maximum operating value.

14. The method of claim 13, wherein the stopping is initiated prior to the current flowing through the one of the switches achieving the maximum operating value.

15. The method of claim 12 further comprising, responsive to the current flowing through the one of the switches exceeding the predetermined threshold and the pulse width modulated signal for the other of the switches having the low state, maintaining the driving.

16. The method of claim 12, wherein the electric machine is a motor or generator.

17. The method of claim 12, wherein the power converter is an inverter.
